(19) United States
(12) Patent Application Publication
(10) Pub. No.: US 2015/0160264 A1
(43) Pub. Date: Jun. 11, 2015

(54) WIRELESS COUPLING FOR RF CALIBRATION AND TESTING OF WIRELESS TRANSMITTERS AND RECEIVERS

(71) Applicant: DockOn A.G., Zurich (CH)

(72) Inventors: Patrick Antoine Rada, San Diego, CA (US); Alexandre Dupuy, San Diego, CA (US); Grant Kumataka, San Diego, CA (US); Jonathan Neil Bringuier, Carlsbad, CA (US); Richard Olesco, National City, CA (US)

(21) Appl. No.: 14/565,379

(22) Filed: Dec. 9, 2014

Related U.S. Application Data
(60) Provisional application No. 61/913,789, filed on Dec. 9, 2013.

(51) Int. Cl. G01R 1/07

(52) U.S. Cl. CPC G01R 1/07

(57) ABSTRACT

A wireless coupling method is suitable for use in calibration and testing of a radiofrequency device under test (DUT). The DUT includes a printed circuit board having one or more integral antennas. The wireless coupling method comprises the use of a test fixture to position the DUT a prescribed distance from a reference unit comprising a second printed circuit board with one or more similar integral antenna(s). Each antenna of the reference unit is aligned optimally to a corresponding antenna of the DUT for transmitting or receiving RF signals in one or more frequency channels in accordance with a test procedure script. Test equipment is coupled to the antennas and is used for measuring or generating each test of the test procedure and saving the measurements in memory.

### CROSS REFERENCE TO RELATED APPLICATIONS

This application claims benefit under 35 U.S.C. §119(e) of Provisional U.S. Patent Application No. 61/913,789, filed Dec. 9, 2013, the contents of which is incorporated herein by reference in its entirety.

### TECHNICAL FIELD

This disclosure relates to an over the air (OTA) test method and related test fixture and reference unit for testing accurately the radio frequency (RF) part of a wireless product.

### BACKGROUND

Wireless devices with an RF transmitter (TX) or receiver (RX) and an antenna generally require individual testing and calibration of each unit manufactured, even when a product is produced in large quantities. It is usual in the wireless industry during production to calibrate and/or verify the transmitter section performance, and to do so at various frequencies, power levels, and channels, with various communication protocols, data rates and modulation types. It is also usual to verify the performance of the receiver section, mainly the RF maximum sensitivity.

Testing of RF parts is usually done in conducted mode (with a test conductor physically in contact with a conductor on the device under test (DUT). This usually includes a controlled impedance setup, since RF requires very good impedance adaptation for in-target performance. To achieve this, the critical connection has to be maintained with a good impedance match and without changing impedance between testing, for example, the RF connector(s), RF Switch-connector(s), coaxial probe(s) and special layout pads, and with simple probe(s) or spring/conductive contact(s).

### SUMMARY

This disclosure includes a wireless coupling method for use in calibration, testing and verification of a radiofrequency (RF) device under test (DUT). The DUT, comprises a printed circuit board having one or more integral antennas. The method comprising the steps of: using a test fixture to position the DUT at a prescribed distance from a reference unit comprising a bare board with one or more similar integral antenna(s), wherein each said reference antenna of said reference unit is aligned optimally to a corresponding antenna of the DUT and coupled wirelessly for transmitting or receiving RF signals over the air at one or more frequencies or frequency channels, one or more frequency bandwidths, one or more power levels, with one or more communication protocols, data rates and modulation types, in accordance with a test procedure; and using a test equipment connected to said reference antenna(s) for measuring or generating each signal of the test procedure and saving the measurements in memory. An example of frequencies are 2412 MHz and 2452 MHz, an example of frequency channels are channels 6 and 9 per IEEE 802.11b, an example of frequency bandwidth are 40 MHz and 80 MHz as per IEEE 802.11ac, an example of power levels are 10 dBm and 17 dBm, an example of communication protocols are 802.11b and 802.11ac, an example of data rate is 1 Mbps and 300 Mbps, and finally an example of modulations are direct sequence spread spectrum and 4×4 multiple inputs multiple outputs MIMO orthogonal frequency division multiplex OFDM with 256-ary quadrature amplitude modulation 256-QAM.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF FIGURES

FIG. 1A depicts a prior art device under test (DUT) radio-frequency (RF) calibration connectivity with a RF switch-connector.

FIG. 1B depicts a modified prior art DUT RF calibration connectivity with a RF switch and resistors R1 & R2 that can be unsoldered (R1) soldered (R2) after test.

FIG. 1C depicts another modified prior art DUT RF calibration connectivity with a RF PCB coaxial pad that can be soldered after test.

FIG. 2A depicts a DUT for use with RF calibration connectivity using antenna coupling in accordance with an embodiment.

FIG. 2B depicts a DUT for use with alternative RF calibration connectivity using antenna coupling in accordance with an embodiment.

FIG. 3A depicts an example antenna coupling test station and a gold unit DUT for calibrating the test station itself in accordance with an embodiment.

FIG. 3B is a flowchart of the test station calibration process used in FIG. 3A in accordance with an embodiment.

FIG. 4A depicts an example antenna coupling test station and regular DUT for testing and calibrating the DUT in accordance with an embodiment.

FIG. 4B is a flowchart of the automatic DUT testing and calibration process of FIG. 4A in accordance with an embodiment.

FIG. 5A depicts an optional process of station verification over the air in a block diagram in accordance with an embodiment.

FIG. 5B is a flowchart of the process in FIG. 5A in accordance with an embodiment.

FIG. 6A depicts an optional process of station verification over the air in a block diagram with a pseudo gold unit in accordance with an embodiment.

FIG. 6B is a flowchart of the process in FIG. 6A in accordance with an embodiment.

FIG. 7 depicts an example test procedure in accordance with an embodiment.

FIG. 8A depicts a top view of an embodiment of a test fixture without a DUT.

FIG. 8B depicts a front side view of an embodiment of a test fixture with a DUT.

### DETAILED DESCRIPTION OF ILLUSTRATIVE EMBODIMENTS

This disclosure describes methods and apparatuses for improved testing and calibration of devices with a radio frequency (RF) transmit and receive (TX/RX) component and an antenna integrated, for example, on a printed circuit board (PCB). The improved methods use antenna coupling and do not require physical RF conductivity with a device under test (DUT). The improved methods instead use a wireless or over-the-air (OTA) coupling test procedure with a careful alignment between antennas in the DUT and antennas in the test system. Additionally, methods and apparatuses for pre-calibration and verification of the test system itself using a calibration unit called a gold unit DUT or a pseudo-gold unit DUT are also described. Typically, a test system itself will be pre-calibrated with a gold unit DUT or pseudo-gold unit DUT prior to testing and calibration of an actual DUT.

In contrast with OTA methods, known conducted mode testing described above, requires physical contact with a DUT using male or female connectors on the device under test, and the cost of such connectors is not negligible. For example costs can be in the range of $0.05 to multiples dollars per connector. Also, without an operator manually connecting a cables to these connectors by hand, a conducted mode RF connection can require the additional costs of a mechanical jig with RF head/connector such as a semi-automatic (RF probe arm device to push manually) or fully automatic (pneumatic device) physical connection system.

Due to these costs and other reasons, an over-the-air method for calibrating and testing the RF portion of a DUT has been a goal for years for many companies active in the development, testing, manufacturing and sale of wireless transceivers. OTA calibration and testing should not to be confused with over-the-air subsystem verification tests such as simple wireless connectivity tests, link establishment/connectivity, or data throughput. Such subsystem verification tests have been done over the air for various wireless industries such as Wi-Fi, cell phone, various analog transceivers, etc., with some success. However, when the requirements get more demanding, such as RF calibration and verification, reliability and reproducibility of over-the-air testing becomes problematic.

As an example of more demanding requirements, take a typical Institute of Electrical and Electronics Engineers (IEEE) standard 802.11n for Wi-Fi with a carrier frequency in the 2.4-2.5 GHz band with multiple input, multiple output (MIMO) 2×2 40 MHz bandwidth access point. After the RF calibration and verification has been done, the product is assembled, the retail software downloaded, and the product tested in OTA mode for bi-directional throughput at maximum data rate and simulated at maximum range (with reference antennas and attenuation to a reference wireless client unit). A device with higher data and throughput rates is desirable. In this case the maximum achievable data rate is 300 Mbps and the maximum achievable throughput rate (effective payload) is about 150 Mbps. As the device is tested in a noisy industrial environment in a medium size shielded box, say of 50 cm by 50 cm by 30 cm with RF absorbent material on the inner walls, the minimum pass/fail value for a typically good production yield is about 100 Mbps. Typical +/−3 sigma variance across individual DUTs may be found to be +/−20 Mbps around an average of 128 Mbps so most units would pass the final production test in this example since 128 Mbps minus 3 sigmas is above the minimum requirement of 100 Mbps. However, more demanding requirements occur, for example, where a Wi-Fi product is a commercial grade Wi-Fi access point, and where the minimum pass/fail requirement value may be pushed up to 120 Mbps. With such higher requirements applied to the same devices using the same test stations, it would be difficult to pass most of the devices since many are below 120 Mbps and the production yield could be problematic and test results may not be sufficiently reliable or repeatable since the test setup does not allow for such high reliability and low variance.

Embodiments of OTA testing and calibration may achieve improved accuracy and repeatability and increase as well the average data rate to 138 Mbps for the same devices. This may be due, in part, to precise and short over the air coupling distance, and may have a tighter +/−3 sigma variance of e.g. +−/17 Mbps, therefore significantly increasing the production yield without any change in the device under test or to the test specification since 138 Mbps minus 3 sigmas is above the requirement of 120 Mbps. The methods described herein cover a unified wireless coupling solution (RF TX calibration, RF TX/RX verification, and throughput verification), and further include the ability to accurately calibrate and verify the RF transmit section and review power values including error vector magnitude (EVM), transmit quality, etc. It may be noted that the higher the carrier frequency, the more difficult this is to do. As an example, an OTA test in the 2.4 GHz band range, for example for Wi-Fi standards IEEE 802.11b, 802.11g, and 802.11n, may be of medium difficulty, while an OTA test in the 5-6 GHz band range, for example for IEEE Wi-Fi standards 802.11a, 802.11n or 802.11ac, are higher difficulty and more challenging to reach with accuracy and reproducibility.

OTA testing embodiments are enabled, in part, based on the antenna design of the DUT. There have been prior attempts to test DUTs without a physical RF connection by coupling wirelessly directly with the DUT's one or more antennas, but the results have been non-satisfactory for various reasons. Two of these reasons relate to DUT antenna design challenges. The first is finding DUT antennas for 2.5 GHz and 5 GHz that can be integrated in the printed circuit board (PCB) and that have high performance versus standard non-PCB dipole (fairly omnidirectional, high efficiency in the order of 60-80%, repeatable performance, small, manufacturable, etc.). The second is finding DUT antennas that exhibit a high magnetic component in order to provide strong coupling at short range and interact mainly with a reference antenna just above it as opposed to sideways, and not to any other antenna. These antenna design goals are the two basic requisites for OTA testing. Compound loop (CPL) antennas meet both requisites.

A CPL antenna is a combination of a loop antenna and a dipole antenna that are electrically coupled in such a way that the magnetic field and electric field are orthogonal to one another even if the antennas are not. It is well known than loop antennas have a strong magnetic field and weak electric field, while dipole antennas have a weak magnetic field and strong electric field. A CPL antenna can have a high efficiency by maximizing both the electric field and magnetic field. Usually a loop antenna has a narrow bandwidth frequency response, while a dipole antenna usually has a wide bandwidth frequency response. A CPL antenna can have a bandwidth of frequency response between that of a loop antenna and a dipole antenna.

There are many benefits to the OTA production testing and calibration embodiments described in this specification. They include reduction in the residual bill of materials (BOM) cost by about US $0.40 per antenna and per DUT, which is achieved by eliminating the RF connector or RF switch/connector on the PCB, and not requiring a separate antenna sub-assembly (antenna, cable & connector). Maintenance requirements are also reduced, in part because there is no need for the RF head or RF cable on the manufacturing test fixture to be changed regularly, for example every 15K cycles. Production quality may be improved, as there is no manual soldering or antenna cable connection(s) after a surface-mount device (SMD) assembly line. Test stations and fixtures are more flexible with a capability to test one product the morning, and another product in the afternoon on the same test station and production test line. Additional benefits include the ability to accelerate and simplify production testing, a more future-proof solution, the ability to improve existing test stations with only minor changes, and a unified wireless coupling solution (RF TX calibration, RF TX/RX verification, and throughput verification).At present RF TX calibration and RF TX/RX verification are done in RF conducted mode with one test station while the throughput data verification is done in another type of test station in wireless mode at a distance of one or more wavelength. With the new concept of OTA testing, calibrating and verifying all the tests can be carried out with the same type of station as short coupling distance as taught in this invention.

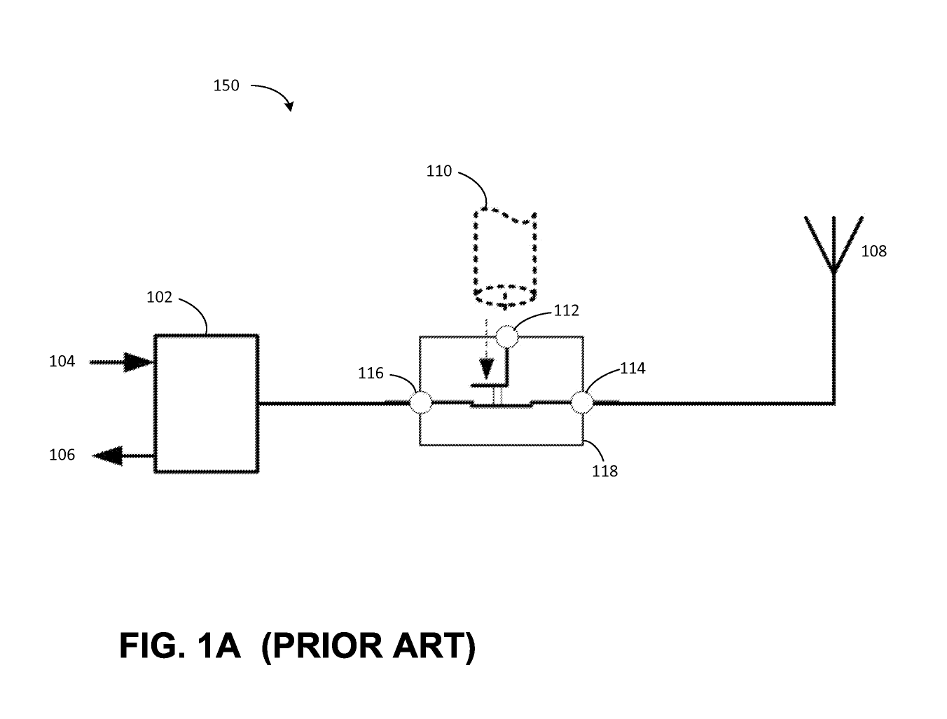

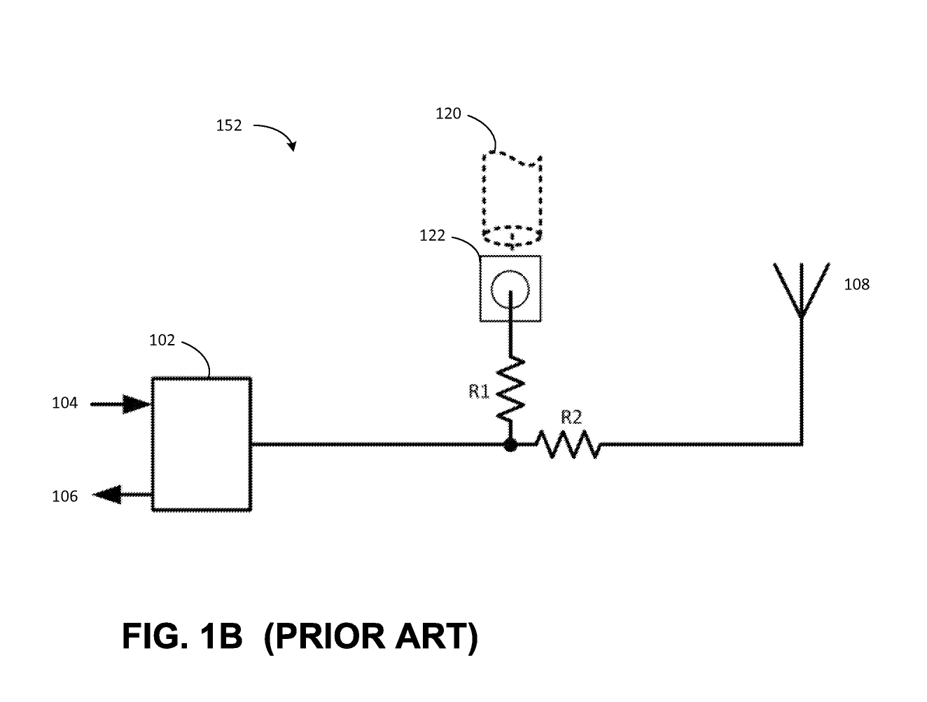

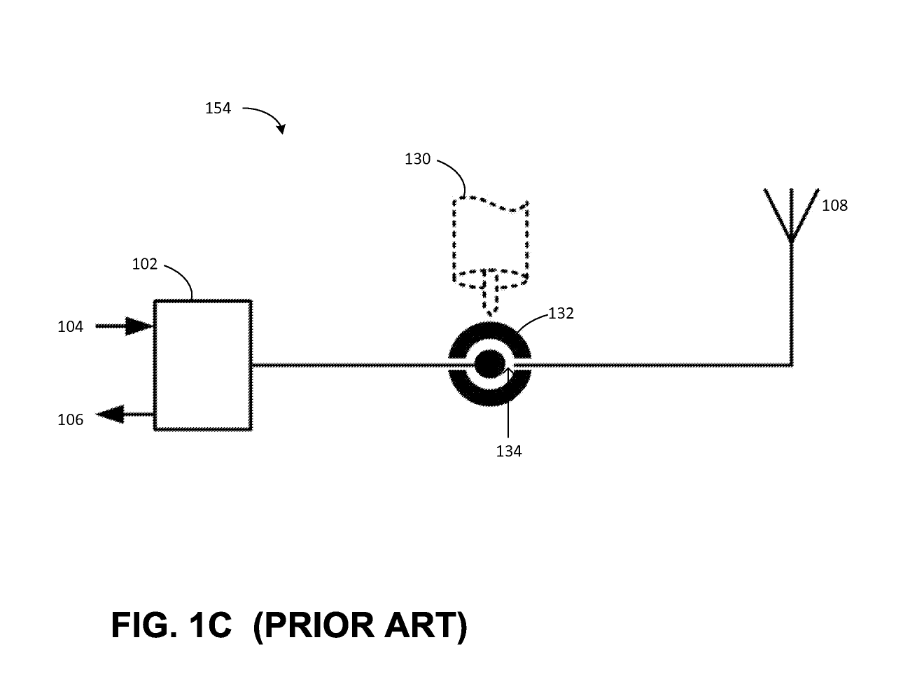

The prior art systems depicted in FIGS. 1A-1C are reviewed first. FIG. 1A depicts a prior art DUT RF calibration connectivity solution 150 that uses a RF female switch connector 118 attached to the printed board in between a RF transceiver 102 (RF TX/RX switch) and a PCB printed antenna 108. It is widely used for testing the RF portion of transceiver in conducted mode while leaving the integral antenna unconnected for the duration of the test. Due to well known RF rules, a RF transceiver 102, with RF TX input 104 and RF RX output 106, cannot be tested with the addition of an RF connector and one or more antenna(s) simultaneously connected. This would generate impedance mismatch and RF energy pick up from the antenna(s) that would make the results inaccurate and non-repetitive.

The RF switch connector 118 permits two modes of operation. First the RF transceiver is connected via an RF probe connection 112 to test equipment while having the printed antenna disconnected at the RF output connection 114. The RF probe 110 connected to the RF probe connection 112 may be a mini coaxial male connector and cable (type 1). This mode permits measurement, testing, calibration, and verification of the RF transmitter and receiver portions connected at the RF input connection 116. Second when no RF probe is connected to the RF switch connector, the RF path is connected to the integral antenna with no or minimal RF mismatch. For example this legacy test and calibration solution can be used for the production testing of a 2×2 MIMO 802.11n router, where each of its transmitter and receiver streams are tested independently of the printed antenna.

The advantages of this solution include that it is straightforward, provides generally good accuracy and tight tolerances in the test results, and is widely used. On the other hand, it increases the residual bill of material by the cost of the RF switch, may exhibit a weak return loss at some frequencies, for instance 5-6 GHz. Another weakness is that the set up can be relatively easy to break when the RF probe is not properly centered and torque is applied to the RF probe, for instance when connected manually by an operator. Another weakness is that affordable RF switch connectors are not suitable for multiple connections and therefore can break or exhibits weak performance after a few cycles of connection-disconnection. Finally the RF probe wears rapidly in mass production and may need to be changed regularly, for instance every 15,000 connection cycles. This is unwanted in mass production where a technician may have to change a few RF probes per multiple test stations per day or per week and recalibrate them for RF tight tolerances.

FIG. 1B shows an alternative implementation of RF calibration connectivity where the costly and fragile RF switch connector 118 has been replaced by a RF female connector 122, and a few resistors R1 and R2. The testing procedure here includes: First, the printed circuit is populated with R1 (typically zero Ohm) and the RF connector 122, but not R2, thus the integral antenna is disconnected. If the layout is designed properly there is a minimal mismatch at the junction of R1 and R2. The RF cable 120 is then connected to the RF connector 122 and, on the other side, to the test equipment, and then the DUT is tested. Second, when that testing is complete, an operator removes R1 and connects R2 (typically zero Ohm). The step of removing may correspond to unsoldering and connecting may correspond to soldering. This is because R1 and R2 need to make a good contact, have minimal insertion loss, low series parasitic inductor and low stray parasitic capacitance. They can be replaced by any RF component or piece of wire or piece of metal that meets the requirement. For instance RF capacitors of low value may be used instead. At this point, the DUT is ready to operate with the antenna 108 and the final assembly of the product to be completed. This solution may be cheaper than the one illustrated in FIG. 1A, may provide a better RF testing accuracy, and may use more robust construction RF switch. On the other hand, a weakness of this solution is that it requires manual rework after the production line soldering which requires more time and may decrease the overall quality or degrade the life of the product, for example when bad soldering is performed. Also, the residual bill of material cost may still be expensive, particularly for a MIMO product or for a multiple standard product, such as a product supporting Wi-Fi MIMO 2×2 as well as LTE 2×2 and Bluetooth.

FIG. 1C is yet another alternative implementation of RF calibration connectivity where the costly and fragile RF switch connector 118 has been replaced by a RF printed board coaxial pad 132 (with both ground and signal) and a RF resistor. The testing procedure here includes: First, the printed circuit is not populated with a resistor at gap 132, thus the integral antenna is disconnected. If the layout is designed properly there is a minimal mismatch at the center coaxial pad. The RF coaxial probe connects to the printed board directly by applying some pressure and, on the other side, to the test equipment, and the DUT is tested. Second, when that test is complete, an operator connects a resistor (typically zero Ohm)(not shown) at the gap 134 between the coaxial pad 132 and the connection to the integral antenna 108. Connecting may correspond to soldering as the RF resistor needs to make a good contact, have minimal insertion loss, low series parasitic inductor and low stray parasitic capacitance. It can be replaced by any RF component or piece of wire or piece of metal or a solder joint that meets the requirement. For instance RF capacitor of low value may be used instead. At this point, the DUT is ready to operate with the antenna and the final assembly of the product be done. The main advantage of this solution is potentially a cheaper cost than FIGS. 1A and 1B. On the other hand, a weakness of this solution is that it requires manual rework after the production line soldering, which requires more time and may decrease the overall quality or degrade the life of the product, e.g., bad soldering. Also the RF design and implementation must be very well done for good performance and low tolerance. It also suffers of the maintenance problem of having to change the RF coaxial probe regularly, for example every 15,000 tests.

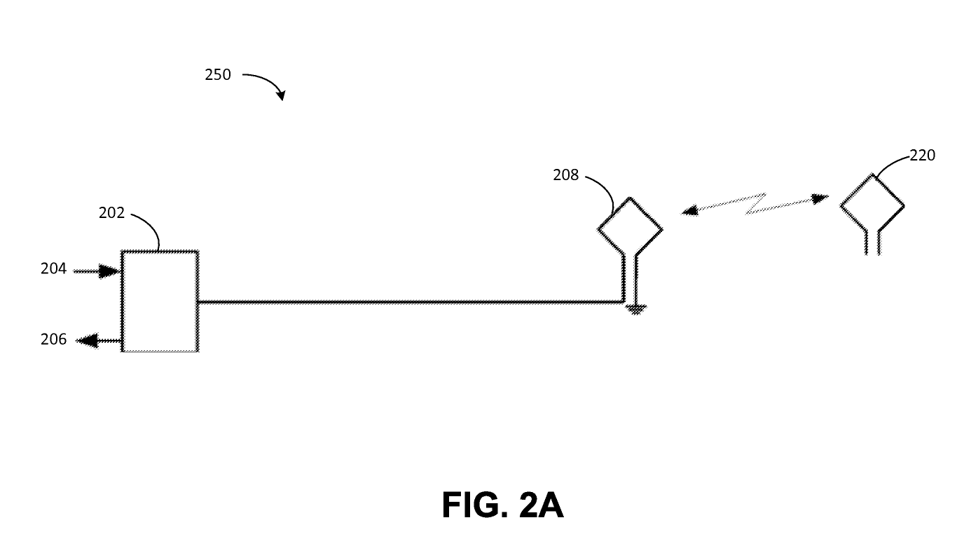

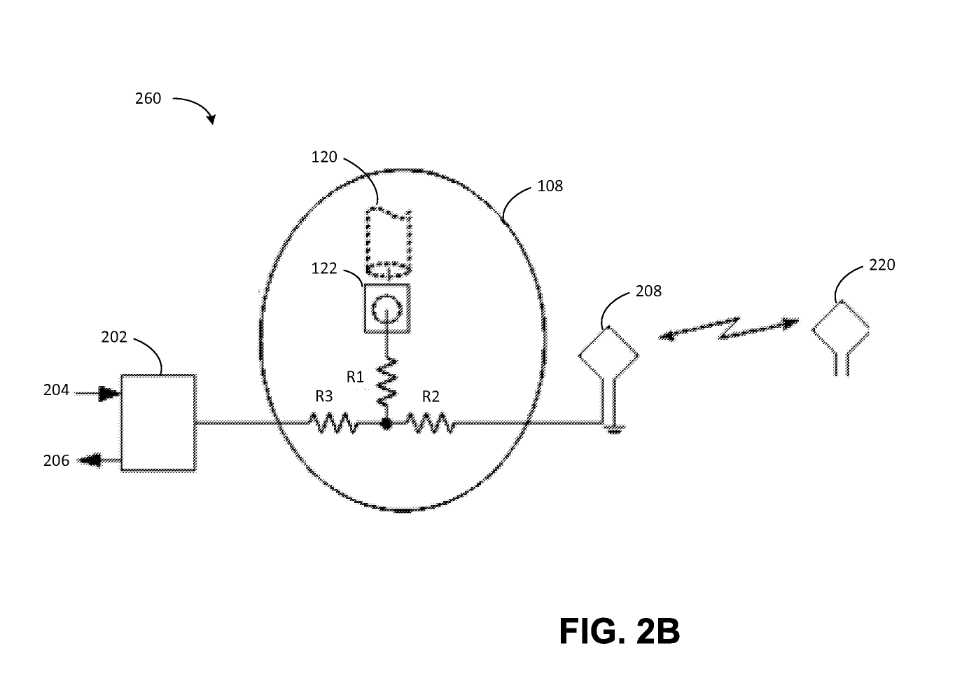

FIG. 2A depicts an embodiment of DUT for use with RF testing and calibration with antenna coupling in accordance with the present disclosure. In this solution, there is no component addition to the printed board to provide RF testing in conducted mode, but instead the testing is done in wireless mode, or said differently, over the air mode with the antenna. DUT 250 simply has a RF transceiver 202 (RF TX/RX switch), with input 204 and output 206, which is directly connected to a PCB printed antenna 208. RF calibration and transmit and receive tests are done with a carefully positioned test system antenna 220.

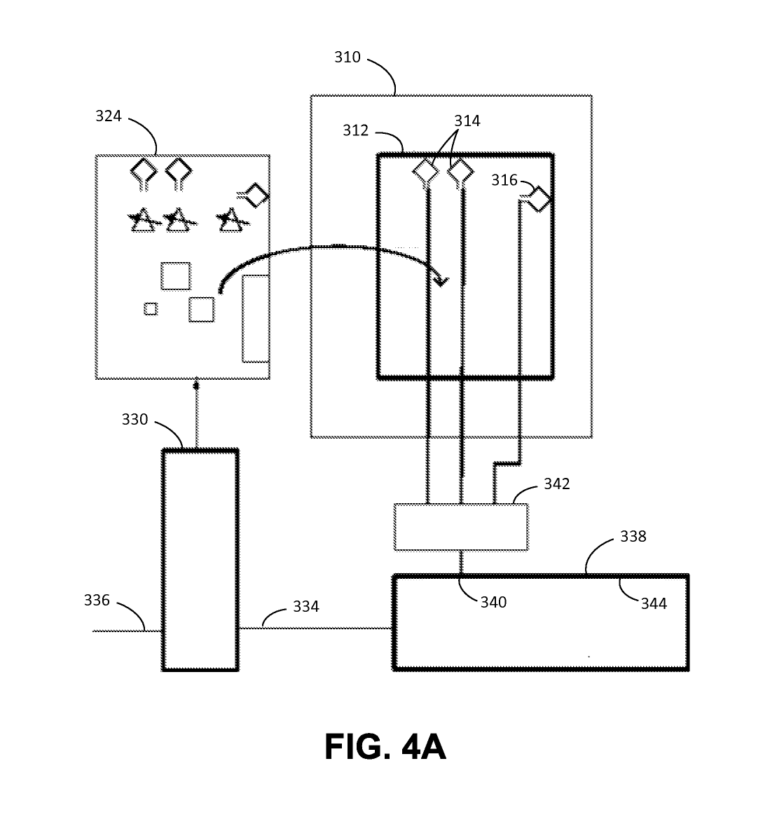

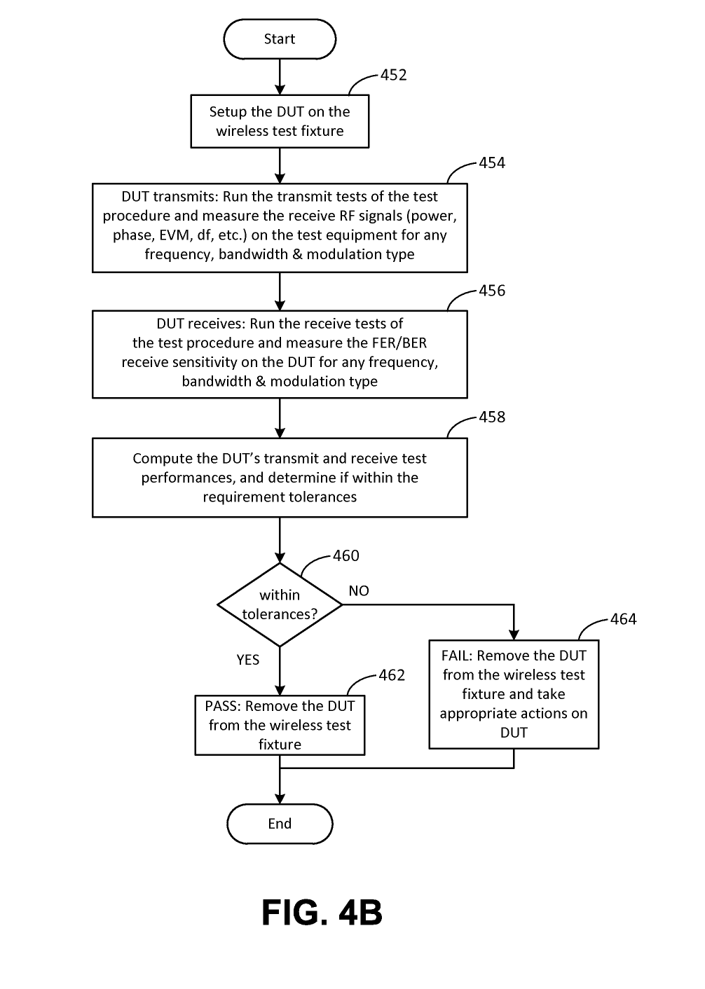

There are numerous advantages to the embodiments disclosed herein. Some of these advantages include that it is the least costly of the solutions discussed per residual bill of materials, is fast and simple to deploy, and provides the highest quality RF testing because it measures the complete RF chain including the one or more antenna(s). Also the measurement is done on the radiated energy versus the power in conducted mode, so the test is closer to a real operating mode. If the distance between antenna 208 the test system receive antenna 220 is short as compared to the wave length of the test signal, there could be some correction needed versus applying the formula for loss with distance which is valid for a range of the wave length. Corrections may include amplitude and phase. Also, in order to take into account variations in performance between individual DUTs, calibration can be done per frequency, per bandwidth, and per type of modulation. An example of a test procedure is shown in FIG. 4B, as further discussed below. With current test equipment, it is possible to create an automatic test script that can include calibration per the various parameters listed above, i.e., per frequency, per bandwidth, and per type of modulation.

It is always preferable to test a complete system versus testing parts of it. Testing only parts of a system requires making assumptions for some untested parts. Untested parts are typically “tested by design” meaning they were testing separately and qualified to provide statistical results, such as typical value and maximum tolerances. This may not be easy to do with integral antennas. Also antenna characteristics may vary from the target performance and have tolerances in the performance. For these reasons, the best testing a provider can do is to test a complete RF system for each DUT and make no assumption. In an example embodiment, the RF test includes the whole RF transmitter, receiver and antenna(s). Printed antenna characteristics mostly vary with the antenna geometry, printed board material, permeability, the geometry and permittivity of each layer if DUT is multilayer, and, finally, proximity of the ground plane to the components.

In an example embodiment, the test method is relative to a fully qualified board called a gold unit board. Relative performance variation is made of an adjustable part and a non-adjustable one. The antenna geometry tolerances and board material characteristics, such as dielectric permeability, are non-adjustable ones. The transmitter power is an adjustable parameter and may be adjusted to the same values as the gold unit per frequency, per bandwidth, and per type of modulation, or even adjusted to compensate in part for non-adjustment variations. Therefore, if the relative performance variation from board to board is tight, the results are accurate. However, if there is some excess variation in antenna performance from board to board due to geometry or printed board material excess tolerances, it will possibly reduce the product performance unless the transmitter power value can be adjusted to compensate for it.

The repeatability from printed board to printed board can be improved by selecting higher grade printed materials and if possible increase the antenna geometry accuracy. Limiting the printed board to two layers is also a simple way to improve the RF performance of the printed board material since no prepreg (glue) is used, and instead, higher quality epoxy is used. Also the fabricated bare printed board can be tested before assembly. A typical way is to design and print a 50 Ohm controlled line with a simple geometry on the panel that includes several boards, and the test its controlled impedance with an instrument such as time domain reflectometry. If the impedance measured is out of specification, it means that either the geometry is inaccurate, the material permeability is out of tolerance, or the layer stuck up is inaccurate or mistaken. The acceptance tolerance for the particular product may be +/−10% or +/−5% for instance. If the acceptance tolerance is not met, the particular printed board should be rejected. On the other side, if the printed board passes the acceptance criteria, it means that the material and geometry are good and a printed antenna is likely to be close to the target performance and within specifications.

This method is applicable per one or more transceivers on each product. For instance, the method could be applied to a Wi-Fi gateway 802.11ac MIMO 8×8 having 8 antennas and an LTE MIMO 2×2 having 2 antennas, a Bluetooth module having 1 antenna, and a GPS system with 1 antenna, for a total of 12 integral antennas.

FIG. 2B depicts a DUT for use with an alternative RF calibration connectivity embodiment using antenna coupling. FIG. 2B is an alternative DUT 260 embodiment that adds an RF female connector 122 and 3 RF resistors R1, R2 and R3 to the DUT of FIG. 2A. This option permits multi-stage testing, starting first with a pre-series or pilot run in RF conducted mode for instance for sampling quality tests. In the pre-series or pilot run for sampling quality, the RF connector 122, R1 and R3 are connected. As per FIG. 1B, one side of an RF cable 120 is connected to the RF connector 122, and the other side of cable 120 is connected to the test equipment. When the test is complete, the resistor R1 is removed and resistor R2 added to make the connection to the antenna 208.

Second, after the pre-series or pilot run, the printed antenna can be qualified separately by connecting the RF connector 122, R1 and R2 (but not R3), and, via coaxial cable 120 attached to the RF switch 122, to the test equipment and a receive coupling antenna 220 also connected to another port of the test equipment. Typical test equipment would include a network analyzer to measure the amplitude and phase, return loss, attenuation, and other values per each frequency or range of frequencies.

Third, R2 and R3 are connected (no R1, leaving RF connector 122 disconnected) so that transceiver 202 is connected to the antenna 208. Third stage testing may be done in the manner described with respect to FIG. 2A. As before, the RF resistors can be replaced by other RF components such as capacitors. This is a flexible solution that can be used for multiple characterizations and as well for mass production. Other benefits and weaknesses are similar to those of FIG. 2A.

Variations of the three-stage process described with FIG. 2B can also be performed. For example, just the first and third or second and third stages may be performed.

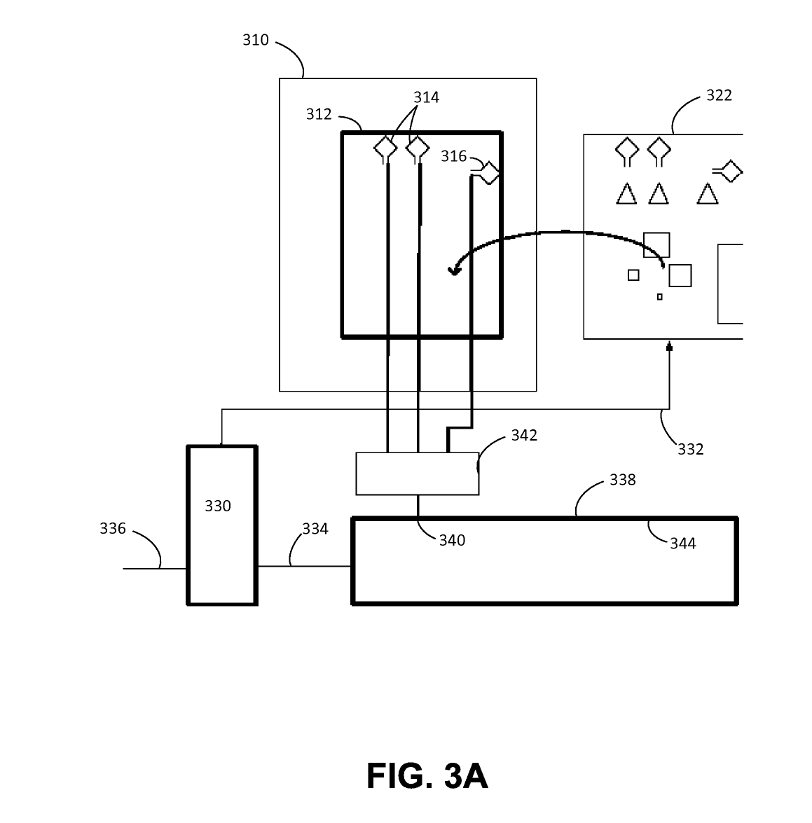

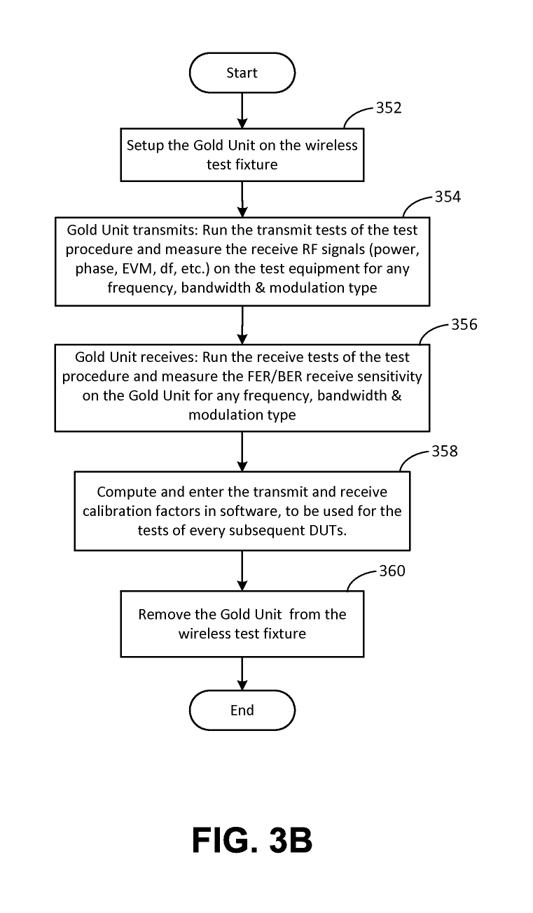

FIG. 3A depicts an example antenna coupling test station and a gold unit DUT for calibrating the test station itself. For test stations that use antenna coupling, the setup includes a standard personal computer 330 with test software, connected by computer network 334, such as Ethernet, to standard RF measurement equipment 344, and optionally additionally connected to a local computer network 336. RF measurement equipment 334 may typically be a vector signal analyzer such as a LITEPOINT VSA/VSG, with a simple RF combiner 342 connected at RF Port #1 340, and nothing connected to RF Port #1 338. RF combiner 342 may have different numbers of connections and, for example as depicted here, may be a 3-1 RF combiner, with three connections to the text fixture 310, and one connection to RF measurement equipment 344. The test fixture 310 may be a generic wireless test fixture, containing wireless coupler fixer 312 (or reference unit) that is a dedicated printed board that can be a bare board version of the devices to be tested (bare board version of the DUT) with permanently attached cables to the combiner 342. As depicted in FIG. 3A, wireless coupler fixture 312 may include two 2.4 GHz antennae 314 and one 5 GHz antenna which may match a possible DUT with 2×2 2.4 GHz 802.11n and 1×1 5 GHz 102.11n. Calibration of the test station further requires a gold unit DUT 322. The gold unit DUT also has a similar antenna layout as the wireless coupler fixture 312 and the actual DUT. The gold unit DUT is a DUT that has previously been carefully lab tested and qualified such that several of its properties are known with confidence. The gold unit DUT may have computer network connection 332 to computer 330, for example, with Telnet.

The test fixture 310 allows for placement of a DUT (or gold unit DUT) into the test fixture with physical positioning elements that ensure careful position in all three dimensions, and with accurate and stable spacing between the wireless coupler fixture 312 and the DUT placed near it. In the case of a DUT and wireless coupler fixture 312 that both include a PCB with the tested antennas printed on the PCB, the physical positioning of the DUT PCB will typically be parallel and at a prescribed distance to the wireless coupler fixture 312, with corresponding antennas on the DUT and the wireless coupler fixture being positioned closest to and aligned with each other, i.e., 3 mm. That is, an antenna A on the DUT is closer to the corresponding antenna on the wireless text fixture that will test that A, than it is to any other antennas on the wireless test fixture. Since the optimal type of printed antenna, such as a CPL antenna, exhibits a strong magnetic field, it will preeminently provide good coupling at short distances. The key feature is that it provides a very good coupling at short range to the target aligned antenna and very bad coupling to any adjacent antenna(s) because the magnetic field coupling strength decreases with the cube of the distance. On the other side, at short range it permits some tolerance of the antenna to antenna placements without drastic change in coupling performance. For instance, the coupling antennas may be positioned at 3 mm +/−0.2 mm with a horizontal displacement of +/−0.5 mm and still provide a coupling value within 1 dB of accuracy. In contrast, a dipole antenna or any non-optimal integral antenna may couple better to adjacent antennas and vary widely from printed board to printed board, which makes the test difficult or inaccurate, thereby defeating the purpose of RF calibration over the air.

As shown, the process of calibrating the station is simple and does not require external equipment such as a network analyzer. The method is also advantageous because the calibration is done the same way as it is measured. The calibration procedure is simple and fast and requires just a few steps when integrated with software, as is further described in FIG. 3B.

One application for this method is Wi-Fi at 2.4-2.5 GHz and 5-6 GHz IEEE802.11b, g, a, n, ac. Of course, other WLAN or WAN standards could benefit from this embodiment, such as Bluetooth, Bluetooth LE, Zigbee, Ziwave, GSM, LTE, WCDA, GPRS, WIMAX, IoT, and various wireless standards at 69 GHz, 169 MHz, 433 MHz, 868 MHz, and more generally, any wireless transmitter, receiver or transceiver.

It is important for the manufacturing plant to get at least one gold unit DUT, for example from a research and development department. A gold unit DUT may be fully qualified in performance, including RF conducted mode, antenna characteristics (gain, efficiently, BW, etc.), wireless at 2 meters or more, and throughput wireless data performance with range (indoor, outdoor or both). With such a fully qualified gold unit DUT, the test station calibration becomes exceedingly simple and fast. This may save a lot of time for manufacturers to prepare, start and ramp up the production of wireless units. It does not require one or more network analyzers in the production floor, which is costly and not desirable.

FIG. 3B is a flowchart of the test station calibration process used in FIG. 3A. Firstly, in step 352, the gold unit DUT is placed on the test fixture in place of the DUT. The gold unit DUT is placed at a prescribed position, with it's one or more antennas facing the same corresponding ones of the fix bareboard of the test fixture at close proximity, in a range of 1 mm to 100 mm, for instance 5 mm. There is no physical RF connection, but rather only wireless coupling over the air between antennas, and naturally and power supply, Ethernet, USB, or other digital cables connected. In some implementations, there may be one or pieces of contact making an electrical contact from the ground of the gold unit DUT to the bareboard. This option may improve the reliability of the testing results.

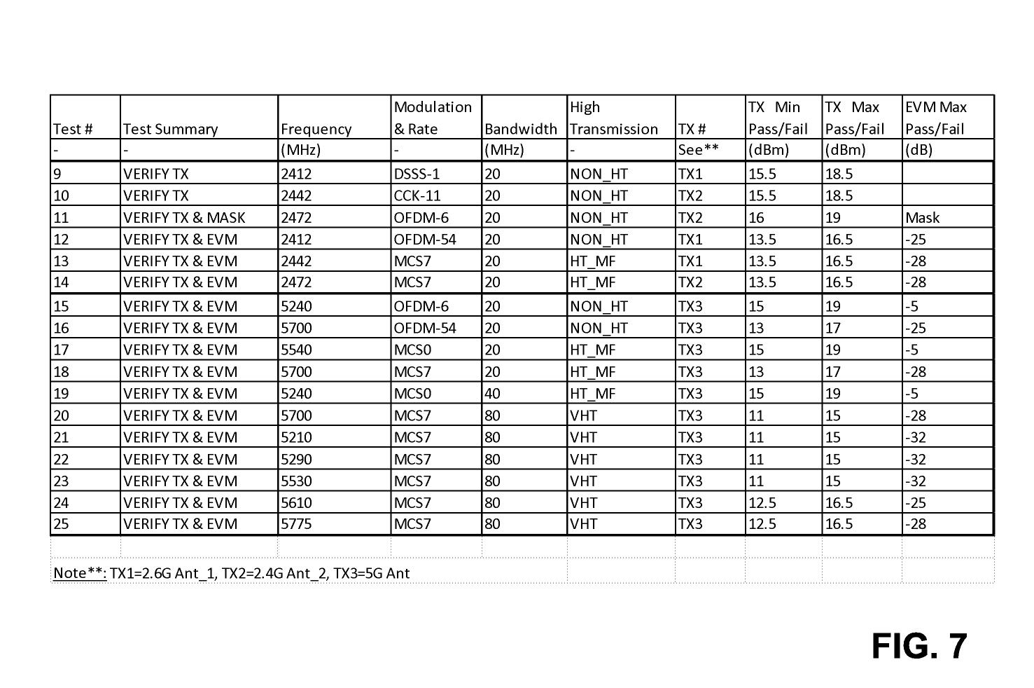

Secondly, in step 354, the RF test procedure starts and does all of the transmit and receive tests. The gold unit transmits to the bareboard over the air, antennas to antennas. The signals are combined in the N to 1 combiner and fed into the measuring equipment. Typically, the power in dBm, the error vector magnitude EVM in % or dB, the center frequency, and optionally the phase in degrees, are measured per each frequency, bandwidth, and modulation type as per the test procedure. An example of the test procedure is provided in FIG. 7.

Thirdly, in step 356, the measuring equipment generates the signals with high to low amplitude and feeds them to the gold unit through the same setup and the gold unit receives the signal from the bareboard over the air, antennas to antennas. Usually the signal is sent at the lowest power level minus the setup losses to guarantee the rate of data dictated by the standard. The gold unit computes the number of correct received frames and calculates the frame error rate FER or the bit error rate BER per each frequency, bandwidth, and modulation type as per the test procedure. Finally, the computer gets the data through the digital connection from the gold unit.

Fourthly, in step 358, the software computes the calibration factors for each test in transmit and receive mode. These calibration factors are stored in memory and will be used for any subsequent DUT calibration. For instance, in one test the gold unit may transmit a signal with 20 dBm of power. If this signal is received by the measuring equipment at 11 dBm, it means that the combination of over the air losses and the setup (that is losses in the cables), in the combiner, etc., add to 20 dB-11 dB=9 dB. Since the gold unit is fully calibrated and the testing equipment is as well, the difference in power corresponds accurately to the total calibration loss for this test (per each frequency, bandwidth, and modulation type). Later on when testing a DUT for the same test, a measured power of 10 dBm on the instrument will have 9 dB of calibration loss added to find out the right transmitted value from the DUT, that is 19 dBm. Fifthly, in step 360, the gold unit DUT is removed from the test fixture.

FIG. 4A depicts an exemplary antenna coupling test station and regular DUT for testing and calibrating the DUT in accordance with an embodiment. The example DUT 352 as depicted here is another 2×2 antenna plus 1×1 antenna product. The exact same hardware setup is used versus the one for station calibration setup described under FIGS. 3A, except that the DUT 324 is used instead of the gold unit DUT 322. Software on the computer 330 is different since this time instead of reading and storing from a reference gold unit DUT 324, the test procedure may consists in calibrating and verifying the DUT 322 relative to the gold unit DUT 324.

FIG. 4B is a flowchart of the automatic DUT testing and calibration process of FIG. 4A. Firstly, in step 452, the DUT is placed on the test fixture in the same fashion as the gold unit DUT was placed in FIG. 3A. The one or more antennas are facing the same ones of the fix bareboard of the text fixture at close proximity, in a range of 1 mm to 100 mm, such as 5 mm. There is no RF connection, but rather wireless coupling over the air between antennas and only power supply, Ethernet, USB, or other digital cables connected. In some implementations, there may be one or more pieces of contact making an electrical contact from the ground of the DUT to the bareboard. This option may improve the testing results reliability.

Secondly, the RF test procedure starts and does all of the transmit test in step 454 and receive tests in step 456. The DUT transmits to the bareboard over the air antennas to antennas. An example of test procedure is provided in FIG. 7.

Thirdly, in step 456, the measuring equipment generates the RF signals with high to low amplitude plus the calibration factors and feeds them to the DUT through the same setup previously described and the DUT receives the signals from the bareboard over the air antennas to antennas. The DUT computes the number of correct received frames and calculates the frame error rate FER or the bit error rate BER per each frequency, bandwidth, and modulation type as per the test procedure. Finally, the computer gets the data through the digital connection from the DUT.

Fourthly, in step 458, the software adds up the calibration factors for each test in transmit mode. Thereafter, in step 460, it compares the transmit and receive results versus the gold unit DUT and determines if each result is within the requirement tolerances. If yes, the DUT is deemed passing the RF tests in step 464. If at least one test fails, the unit fails the tests in step 462. Various appropriate actions can be taken if the DUT fails, for instance retesting a number of times. Fifthly, in step 464 or step 462, the DUT is removed from the test fixture.

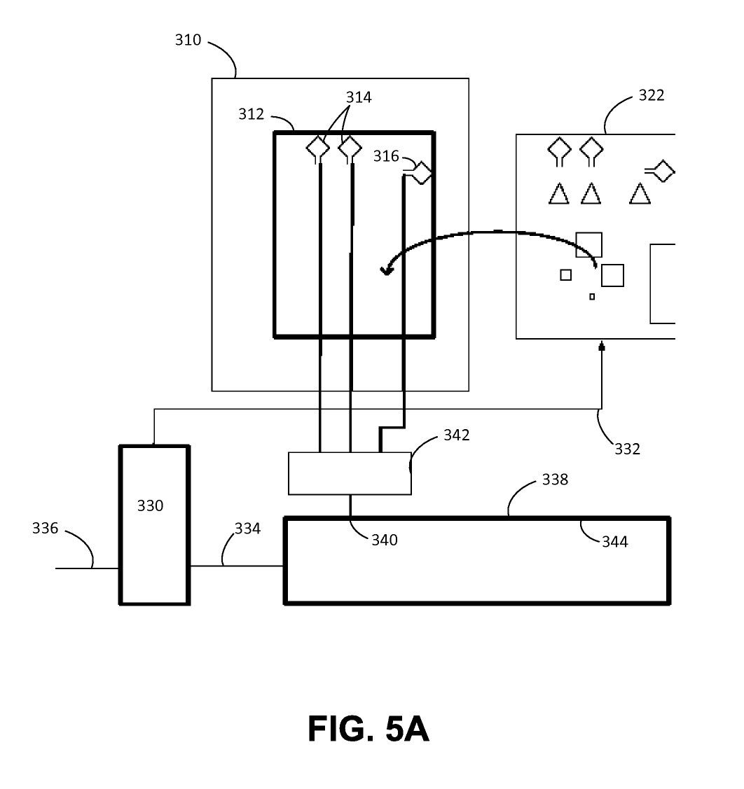

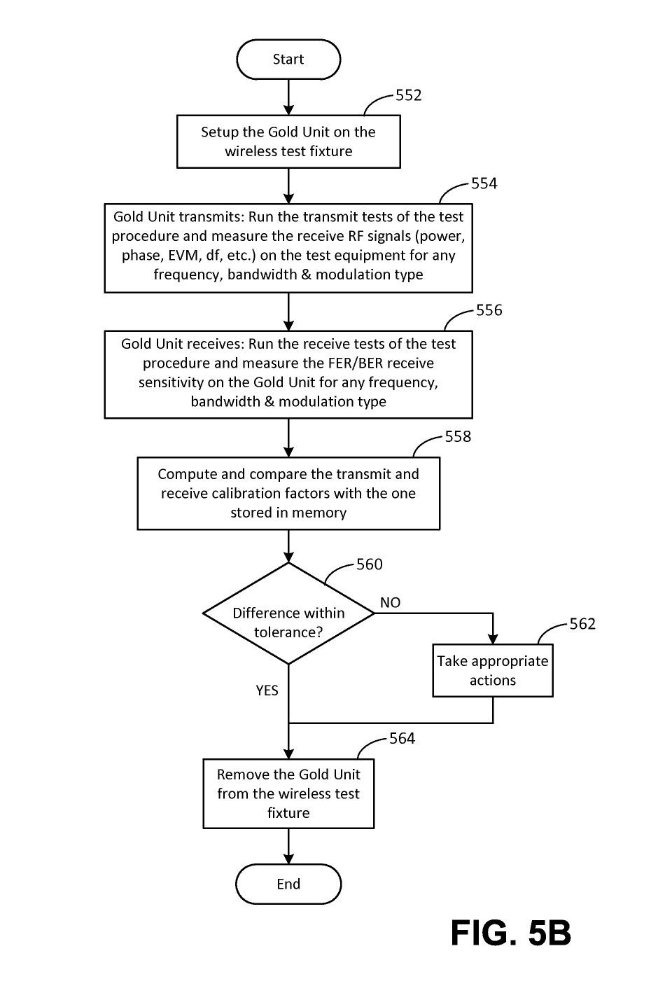

The test fixture can be placed in a shielded box or shielded room to improve isolation with external EMI noise and noise from other concurrent test stations in progress. FIG. 5A depicts an embodiment and FIG. 5B shows a flowchart of an optional process for verification of an antenna coupling test station. The hardware setup is identical to the one of FIG. 3A, but the software and test flow chart are different. In this optional process, the gold unit DUT may be used to verify the performance of the test station and test fixture at any time, for instance, if there is a doubt that something is wrong. For instance, if the last 5 DUTs have failed the test, is the problem coming for the DUTs or the station? A quick verification with the gold unit DUT can alleviate this concern and gain time in mass production.

FIG. 5B depicts the station calibration process flow chart. The steps are identical to that described with respect to FIG. 3B, until the end of the transmit and receive tests. In FIG. 5B, the computer computes the results and compares those results with results stored in memory. The compared results should be identical or very close to the stored results. If so, the software confirms the calibration of the station (pass). If not, it shows which parameters are different. Appropriate actions should be taken at this stage (failing). An example of an action to be taken may include putting the test station on hold and calling for a technician to troubleshoot the problem.

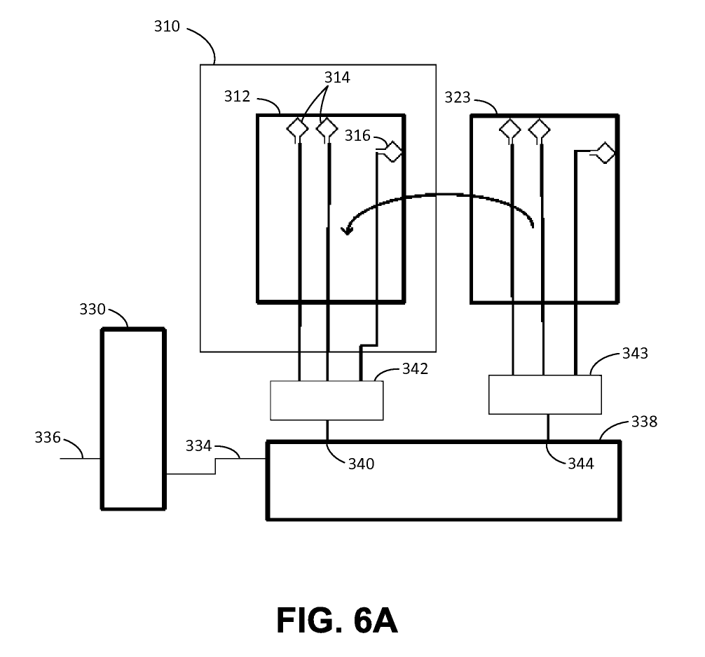

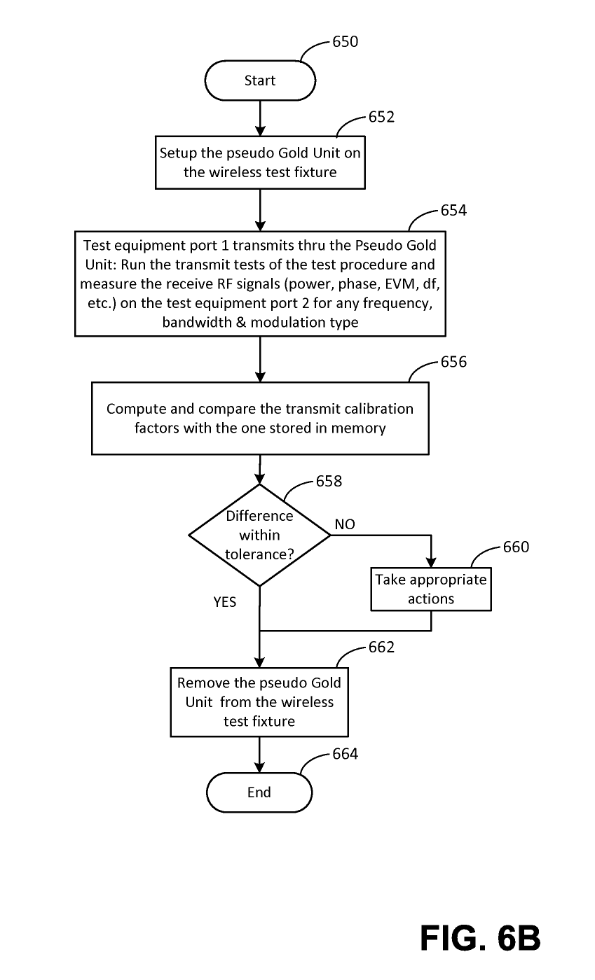

FIG. 6A shows yet another useful embodiment of the Station Verification Process that utilizes a pseudo gold unit DUT that is permanently attached to the test station. The hardware is again similar to the that of FIG. 3A except that gold unit DUT 322 has been replaced with pseudo-gold unit DUT 323, and pseudo-gold unit 323 is connected differently. A pseudo-gold unit DUT is a bare board of DUT where the antennas have been connected to a cable further connected a N to 1 RF switch. As depicted, pseudo-gold unit DUT 323 is connected to 3 to 1 RF switch 343, which is then connected to RF Port #2 344 of RF measuring equipment 338. A pseudo gold unit DUT is very simple to create and calibrate and can be left connected permanently to any station. It may also improve the manufacturing quality since there is no disconnection required and help to accelerate potential problems with the DUTs or with the station. One limitation of the pseudo gold unit DUT is that it permits only transmit tests, but not receive tests, since neither it nor the test equipment has any frame error rate computing receiver. RF Test equipment generally are able to transmit a RF signal with low to high power and on the other side to analyze a mid to high transmit power.

However, some of them do not have a full receiver able to demodulate the signal and compute the FER or BER. If the test equipment has a receiver, then the pseudo gold unit DUT can be used for both transit and receive modes.

FIG. 6B shows the flow chart of the test process. It is similar to FIG. 3B, but includes only the transmit tests; although both transmit and receive tests are done if the test equipments has a receiver. The results of the pseudo gold unit DUT are expected to match the results of the gold unit DUT. The computer therefore computes the differences between the two and validates (pass) the station if any difference is within a tolerance. In the opposite case, the test fails and appropriate actions should be taken as mentioned previously.

FIG. 7 depicts an example test procedure in accordance with an embodiment. Every row of the chart indicates a separate test in a test script or procedure, including the frequency of the test, “Modulation & Rate” indicates communication protocol and rate to be used, the bandwidth of the test, “High Transmission” indicates some parameters for the communication protocol used, which transmitter is used, an pass/fail thresholds for minimum transmit, maximum transmit, and error vector magnitude (EVM) Max.

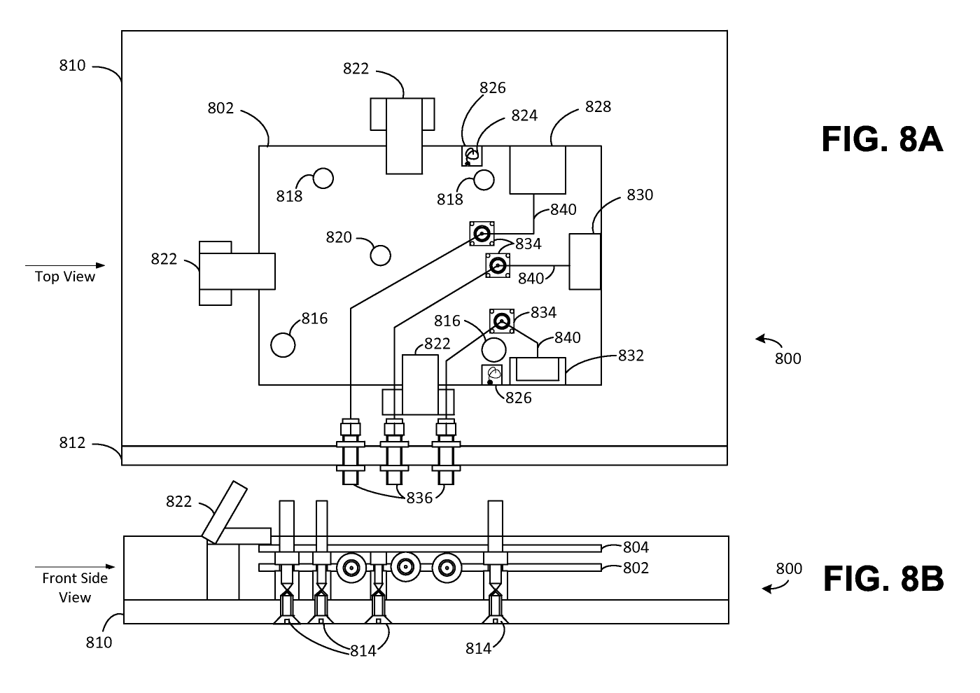

FIG. 8A depicts a top view of an embodiment of a test fixture without a DUT. FIG. 8B depicts a front side view of an embodiment of a text fixture with a DUT. Test fixture 800 is an example test fixture for test station calibration as well as DUT testing, calibration and verification using antenna coupling. It should be understood that many variations of test fixture 800 are possible and can be implementations of test fixture 310 of FIG. 4A. Test fixture 800 comprises a base 810 and side 812, that may be made from hard support plastic, for example 5 mm thick. A reference board 802, such as wireless coupler fixture 312 in FIG. 4A, is more permanently attached to test fixture 800, while DUT 804 may be changed between runs of a test script. DUT 804 in FIGS. 8A and 8B can be replaced with gold unit DUT such as gold unit DUT 322 of FIG. 3A to calibrate the text fixture 800.

Five screws 814 (one of which is hidden in FIG. 8B) with conical heads provide support for both reference board 802 and DUT 804 above it. Support from the screws 814 is provide by alignment poles 816 and 818 and stand 820. The alignment poles may be of two different types, for example 816 being one type, and 818 being another type. The alignment poles 816 and 818 sit atop the screws 814, and may fit though holes inside reference board 802 and DUT 804 to provide alignment between the reference board 802 and DUT 804. Stand 820 goes through reference board 802, but not through DUT 804, instead providing support to keep DUT 804 at the prescribed distance from the reference board 802. The removable DUT 804 is additionally held in place by three retractable pinching mechanisms 822 on three sides of the DUT 804.

The top view of FIG. 8A depicts the reference board 802 without the DUT 804 installed above it. The antennas 828, 830, and 832 are on top of the reference board 802 (and hence closer to DUT 804 when it is installed). Antenna 828 may be a 5G antenna, antenna 830 may be a first 2.4 G antenna, and antenna 830 may be a second 2.4 G antenna. These three antennas are each connected via 50 ohm lines 840 to separate SMA through-hole connectors 834. The through-hole connectors 834 may be soldered on the bottom, and are connected via lines 838 to SMA through-panel connectors 836. SMA though panel connectors 838 enable connection to test equipment, such as RF measuring equipment 338 via combiner 342 of FIG. 4A.

Although the subject matter of this disclosure has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

What is claimed:

1. A wireless coupling method for use in calibration, testing and verification of a radiofrequency (RF) device under test (DUT), the method comprising the steps of:
positioning the DUT at a prescribed distance from a reference unit, wherein the DUT comprises a printed circuit board having one or more DUT antennas, the reference unit comprising one or more reference antennas corresponding to the DUT antennas, and wherein the positioning including aligning one or more DUT antennas with one or more reference antennas such that corresponding antennas are coupled wirelessly for transmitting or receiving RF signals over the air at one or more frequencies in accordance with a test procedure;
generating one or more DUT RF signals of the DUT test procedure;
measuring the one or more of DUT RF signals with test equipment; and
saving the DUT RF measurements in a memory as DUT measurements.

2. The method of claim 1, further comprising the steps of:
positioning a gold unit DUT at a prescribed distance from the reference unit, wherein the gold unit DUT comprises a printed circuit board having one or more gold unit antennas, wherein the gold unit DUT has one or more known properties, and wherein the positioning includes aligning one or more gold unit antennas with one or more reference antennas such that corresponding antennas are coupled wirelessly for transmitting or receiving RF signals over the air at one or more frequencies in accordance with a gold unit DUT test procedure;
generating one or more test system calibration RF signals of the test procedure;
measuring the one or more of test system calibration RF signals with the test equipment;
calculating a test system calibration loss based on the test system calibration measurements and one or more known properties; and
saving the calibration loss in the memory.

3. The method of claim 2, further comprising the steps of:
calculating a DUT calibration based at least on the calibration loss and the DUT RF measurements; and
saving the DUT calibration in the memory.

4. The method of claim 2, further comprising the steps of:
positioning a pseudo-gold unit DUT at a prescribed distance from the reference unit, wherein the pseudo-gold unit DUT comprises a printed circuit board having one or more pseudo-gold unit antennas connected to a multiport combiner, wherein a common port of the multiport combiner is connected to the test equipment, and wherein the positioning includes aligning one or more pseudo-gold unit antennas with one or more reference antennas such that corresponding antennas are coupled wirelessly for transmitting or receiving RF signals over the air at one or more frequencies in accordance with a pseudo-gold unit DUT test procedure;
generating one or more calibration verification RF signals;
measuring the one or more of calibration verification RF signals with the test equipment; and
verifying the test system by using the calibration verification RF measurements with the saved calibration loss.

5. The method of claim 2, further comprising the steps of:
setting a gain for a transmitter for the test system calibration RF signals to a known gold unit gain; and
setting a gain for a transmitter for the DUT RF signals to the known gold unit gain.

6. The method of claim 1, wherein the prescribed distance is a fraction of a wavelength of a frequency of one or more DUT RF signals.

7. The method of claim 6, wherein the prescribed distance results in a near field coupling configuration with a coupling distance between one or more DUT antennas and one or more reference antennas that is approximately 3 mm for DUT RF signal frequencies below 20 GHz.

8. The method of claim 6, wherein the prescribed distance results in a far coupling configuration with a coupling distance between the one or more reference antennas and the one or more DUT antennas that is one or more wavelengths of the DUT RF signal.

9. The method of claim 1, further comprising the steps of:
setting, according to the DUT test procedure, at least one of power level, frequency channel, data rate, bandwidth, and modulation scheme.

10. The method of claim 1, further comprising the steps of:
connecting antenna cables to a zero stress RF cable connection on the reference unit.

11. The method of claim 1, wherein the step of measuring the DUT RF signals includes measuring one or more of: average transmit power, peak transmit power, minimum transmit power, average error vector magnitude (EVM), minimum EVM, maximum EVM, average phase, minimum phase, maximum phase, transmit power per subcarrier, average EVM per subcarrier, minimum EVM per subcarrier, and maximum EVM per subcarrier.

12. The method of claim 1, further comprising the steps of:
connecting grounds of the DUT and the reference unit by one or more electrical contacts at one or more locations.

13. The method of claim 1, further comprising the steps of:
maintaining the prescribed distance between the DUT and the reference unit within tolerances in X, Y and Z dimensions.

14. The method of claim 1, further comprising the steps of:
maintaining the prescribed distance between the DUT and the reference unit within a range of 1 mm to 50 mm.

15. A test system for calibrating, testing or verifying a radiofrequency (RF) device under test (DUT), comprising:
a reference unit including a printed circuit board with one or more reference antennas, where the reference antennas are compound loop antennas;
a test fixture for holding a DUT at a prescribed distance from the reference unit; and
test equipment for generating and measuring RF signals connected to a computer configured for controlling the test system according to a test procedure and further configured to record DUT test results.

16. The test system of claim 15, wherein the DUT test results are calculated by the computer based on previously recorded test results from a gold unit DUT.

17. The test system of claim 15, further comprising a pseudo-gold unit DUT including a printed circuit board having one or more pseudo-gold unit antennas connected to a multiport combiner, the multiport combiner's common port being connected to the test equipment.

18. The test system of claim 15, further comprising:
a zero-stress RF cable connection configured to connect the test system to the DUT with minimum wear on the test system.

19. The test system of claim 15, wherein the reference unit further comprises:
an integral antenna characterized by a prominent magnetic field, a prominent electrical field, or prominent magnetic and electrical fields.

20. The test system of claim 15, wherein the test fixture is configured for connecting with the DUT using one or more electrical contacts that are one or more of: spring contacts, metal contacts, connector contacts, tip contacts, foil contacts, and metal sheet contacts.
